(19) United States
(12) Patent Application Publication
(10) Pub. No.: US 2015/0318873 A1
(43) Pub. Date: Nov. 5, 2015

(54) ITERATIVE DECODER WITH CONFIGURABLE POOL OF DECODING STAGES

(71) Applicant: SIANO MOBILE SILICON LTD., Kfar Netter (IL)

(72) Inventors: Roy Oren, Magshimim (IL); Ofer Rivkind, Modi'in (IL); Yuri Roytman, Kiryat Ono (IL)

(73) Assignee: SIANO MOBILE SILICON LTD., Kfar Netter (IL)

(21) Appl. No.: 14/265,387

(22) Filed: Apr. 30, 2014

(51) Int. Cl. H03M 13/37

(52) U.S. Cl. CPC H03M 13/3746; H03M 13/3707

(57) ABSTRACT

An apparatus includes a plurality of decoding stages, each configured to perform a decoding iteration of an Error Correction Code (ECC), and control circuitry. The control circuitry is configured to receive two or more input signals that carry data encoded with the ECC, to adaptively select an allocation that specifies a respective number of decoding iterations of the ECC to be performed on each of the input signals, to configure the decoding stages in the plurality in one or more cascades in accordance with the allocation, and to decode the input signals using the cascaded decoding stages.

### FIELD OF THE INVENTION

The present invention relates generally to Error Correction Codes (ECC), and particularly to methods and systems for iterative ECC decoding.

### BACKGROUND OF THE INVENTION

Error correction coding is used in various digital communication systems. Some communication receivers use iterative ECC decoding processes. For example, Nakamura et al. describe an iterative decoding scheme for a mobile digital multimedia receiver, in “Mobile Reception Performance of ISDB-T_{SB} Mobile Multimedia Broadcasting System using the VHF-Low Band,” 2012 IEEE International Symposium on Broadband Multimedia Systems and Broadcasting (BMSB), Seoul, South Korea, June, 2012, which is incorporated herein by reference.

### SUMMARY OF THE INVENTION

An embodiment of the present invention that is described herein provides an apparatus including a plurality of decoding stages, each configured to perform a decoding iteration of an Error Correction Code (ECC), and control circuitry. The control circuitry is configured to receive two or more input signals that carry data encoded with the ECC, to adaptively select an allocation that specifies a respective number of decoding iterations of the ECC to be performed on each of the input signals, to configure the decoding stages in the plurality in one or more cascades in accordance with the allocation, and to decode the input signals using the cascaded decoding stages.

In some embodiments, the two or more input signals are received over a given communication channel, and the control circuitry is configured to adaptively select the allocation based on a condition of the communication channel. In some embodiments, the control circuitry is configured to adaptively select the allocation based on one or more parameters of the input signals. The parameters may include respective data rates of the input signals, respective modulation schemes of the input signals, and/or respective extents of interleaving applied to the input signals.

In some embodiments, a given decoding stage is configured to receive input soft bits, to perform the decoding iteration on the input soft bits, and to re-encode the decoded input soft bits so as to produce output soft bits. In an embodiment, the given decoding stage is configured to select whether to provide as output the output soft bits or the received input soft bits. The given decoding stage may be configured to set respective confidence metrics of the output soft bits depending on a success indication of decoding the input soft bits. In an embodiment, a predefined location in the data contains a predefined bit pattern, and the given decoding stage is configured to set respective confidence metrics of the output soft bits depending on whether the decoded input soft bits at the predefined location match the predefined bit pattern.

There is additionally provided, in accordance with an embodiment of the present invention, a method including receiving two or more input signals that carry data encoded with an Error Correction Code (ECC), for decoding by a plurality of decoding stages that are each configured to perform a decoding iteration of the ECC. An allocation, which specifies a respective number of decoding iterations of the ECC to be performed on each of the input signals, is adaptively selected. The decoding stages in the plurality are configured in one or more cascades in accordance with the allocation. The input signals are decoded using the cascaded decoding stages.

There is also provided, in accordance with an embodiment of the present invention, an apparatus including a receiver front-end and a modem. The modem includes a plurality of decoding stages, each configured to perform a decoding iteration of an Error Correction Code (ECC). The modem is configured to receive two or more input signals that carry data encoded with the ECC, to adaptively select an allocation that specifies a respective number of decoding iterations of the ECC to be performed on each of the input signals, to configure the decoding stages in the plurality in one or more cascades in accordance with the allocation, and to decode the input signals using the cascaded decoding stages.

The present invention will be more fully understood from the following detailed description of the embodiments thereof, taken together with the drawings in which:

### BRIEF DESCRIPTION OF THE DRAWINGS

FIG. 1 is a block diagram that schematically illustrates a Digital Television (DTV) receiver that uses iterative ECC decoding, in accordance with an embodiment of the present invention;

FIG. 2 is a block diagram that schematically illustrates an iteration stage in an iterative ECC decoder, in accordance with an embodiment of the present invention;

FIG. 3 is a block diagram that schematically illustrates an iterative ECC decoder, in accordance with an embodiment of the present invention; and

FIG. 4 is a flow chart that schematically illustrates a method for iterative ECC decoding, in accordance with an embodiment of the present invention.

### DETAILED DESCRIPTION OF EMBODIMENTS

### Overview

Embodiments of the present invention that are described herein provide improved methods and systems for iterative decoding of Error Correction Codes (ECC). In the disclosed embodiments, a receiver comprises a configurable pool of hardware-implemented decoding stages, each configured to perform a decoding iteration of the ECC. The decoding stages can be interconnected in various ways, so as to form one or more cascades, each comprising one or more of the decoding stages. A longer cascade is typically capable of correcting a larger number of errors, and vice versa.

The receiver typically uses the pool of decoding stages to decode multiple input signals that are received simultaneously. In some embodiments, the input signals may differ from one another in their transmission parameters, e.g., in data rate and/or modulation scheme. As such, it is advantageous for the receiver to adaptively allocate cascades of different lengths to different input signals.

In a typical flow, the receiver evaluates the received input signals, decides how many decoding stages are to be performed on each input signal, configures the pool of decoding stages to form the desired cascades, and then decodes each input signal using the respective cascade of decoding stages.

The receiver may assign decoding stages to input signals using various criteria. In some embodiments, the receiver assesses the Signal-to-Noise Ratio (SNR) on the communication channel and the transmission parameters of the different input signals, and selects the desirable cascade lengths based on this information.

For example, an input signal having a low data rate and/or low-order modulation is typically more resilient to errors, and may therefore be assigned fewer decoding stages than an input signal having a high data rate and/or high-order modulation. As another example, the receiver may find that the current SNR is too low for decoding one of the input signals. In such a case, the receiver may decide not to waste decoding resources on this input signal, and to allocate all the decoding stages to the other input signals.

The methods and systems described herein are highly flexible and efficient in adaptively allocating ECC decoding resources to input signals. The disclosed techniques can be used in a variety of systems and applications. For example, in some Digital Television (DTV) protocols, a given channel may carry multiple layers (e.g., video, audio and/or data channels) that may differ in transmission parameters. The disclosed techniques can be used to optimally allocate decoding stages to respective layers.

### System Description

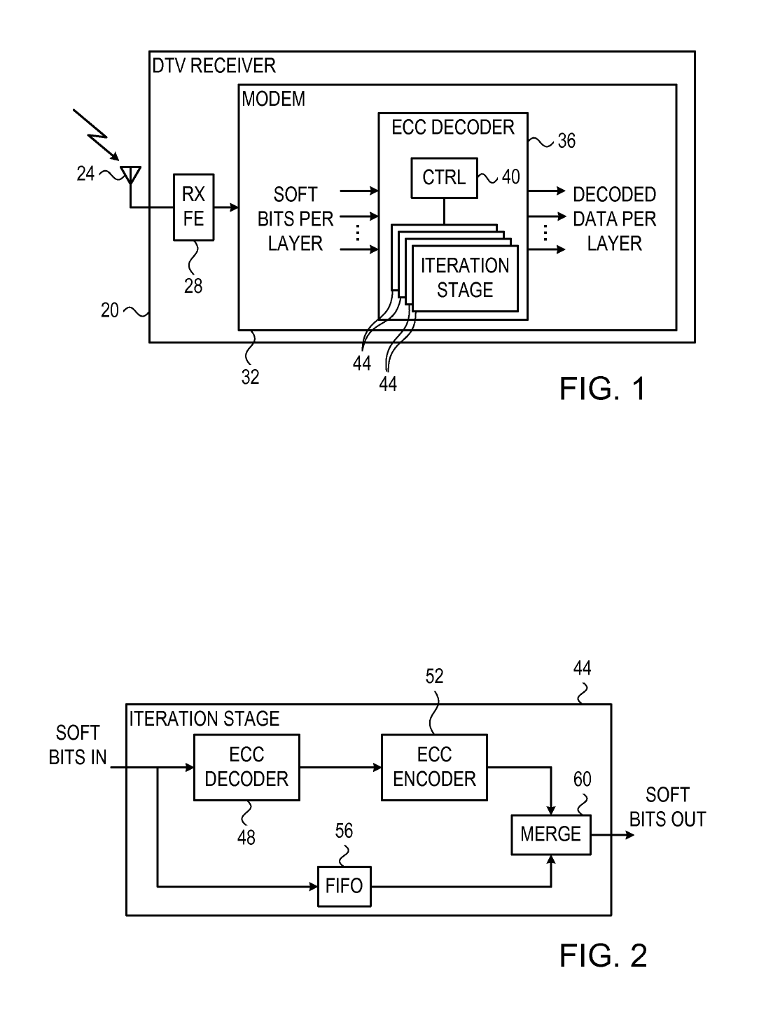

FIG. 1 is a block diagram that schematically illustrates a Digital Television (DTV) receiver 20 that uses iterative ECC decoding, in accordance with an embodiment of the present invention. Receiver 20 receives and decodes DTV signals that are transmitted by a transmitter (not shown). Receiver 20 may be used for receiving and decoding DTV signals in accordance with any suitable DTV format or specification.

Example formats include the various Integrated

Services Digital Broadcasting (ISDB) standards, such as the satellite variant ISDB-S and the terrestrial variants ISDB-T and ISDB-T_{SB}. Another example is hierarchies in the DVB-T standard. Alternatively, receiver 20 can be used for receiving any other suitable format. Although the embodiments described herein refer mainly to digital television reception, the disclosed techniques can be used with any other suitable application and signal type.

At a given point in time, receiver 20 receives a composite signal that typically comprises two or more different input signals. A received ISDB channel, for example, may comprise one or more digital video signals (Standard-Definition or High-Definition), one or more digital audio channels and/or one or more data channels. Each of the input signals is also referred to herein as a layer or hierarchy.

Each layer is transmitted using respective transmission parameters, e.g., modulation scheme and data rate. The transmitter may set the transmission parameters of the various layers independently of one another. Each layer typically carries data that is encoded with an Error Correction Code (ECC). In an example embodiment, the ECC comprises a concatenation of an inner code and an outer code. In ISDB-T, for example, the ECC comprises a concatenation of a convolutional code and a Reed-Solomon (RS) code. Alternatively, however, each layer in the composite signal may use any other suitable type of error correction code or codes.

In the example of FIG. 1, receiver 20 comprises an antenna 24, a receiver front-end (RX FE) 28 and a modem 32. Antenna 24 receives the composite signal on a suitable Radio Frequency (RF) from the transmitter. RX FE 28 down-converts the RF signal to baseband or other low frequency and digitizes the signal. Modem 32 decodes the various layers of the composite signal, so as to decode the data carried by the layers. The decoded data (e.g., video, audio and/or data channels) is provided as output. In particular, modem 32 decodes the ECC that encodes the data carried by the layers.

In an embodiment, modem 32 comprises an iterative ECC decoder 36, which decodes the ECC of the various layers using an iterative decoding process. For this purpose, decoder 36 comprises a plurality of decoding stages 44, also referred to as iteration stages. Each iteration stage is configured to perform an iteration of the iterative ECC decoding process. Decoder 36 comprises a control unit 40, which configures and manages iteration stages 44 using methods that are described in detail herein.

The configuration of receiver 20 shown in FIG. 1 is an example configuration, which is chosen purely for the sake of conceptual clarity. In alternative embodiments, any other suitable receiver configuration can be used. Elements of receiver 20 that are not mandatory for understanding of the disclosed techniques have been omitted from the figure for the sake of clarity.

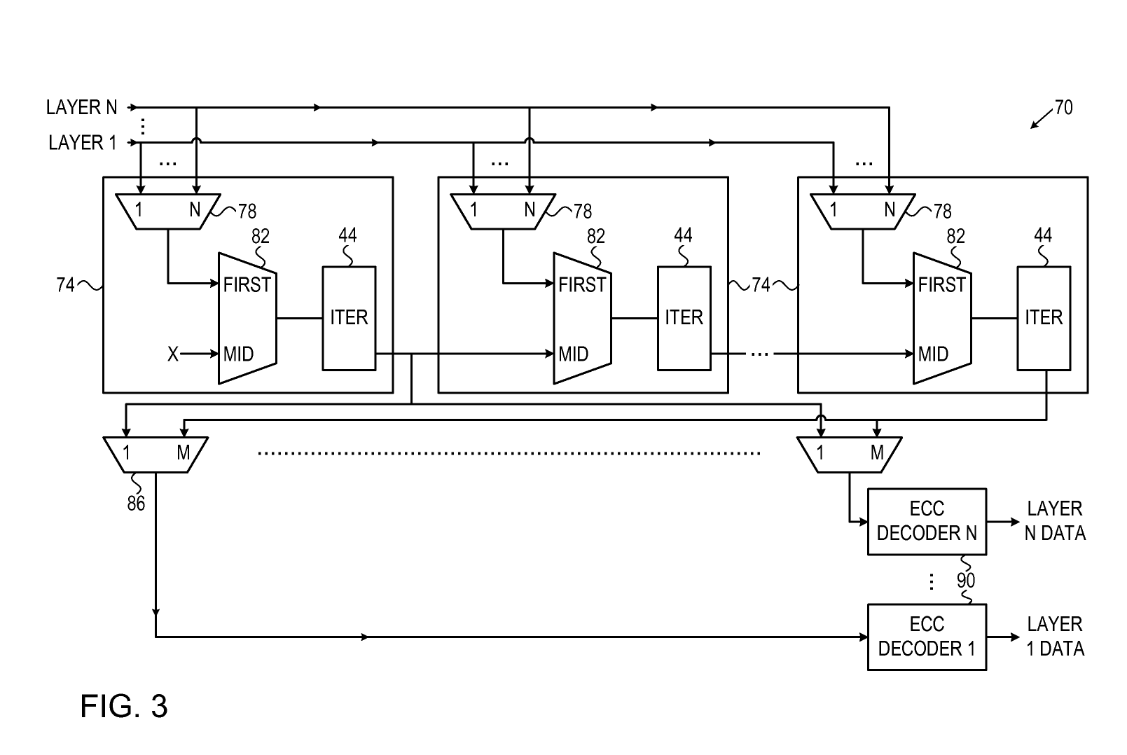

In the present context, the circuitry that handles the configuration of decoding stages 44 (including receiving and analyzing the input signals, defining the appropriate allocation of decoding stages to input signals, and configuring the decoding stages to form the desired cascades) is referred to herein as control circuitry. In the example of FIG. 1, the functions of the control circuitry are carried out by control unit 40. Another example of control circuitry is shown in FIG. 3 further below.

Some elements of receiver 20 may be implemented in hardware, e.g., in one or more Application-Specific Integrated Circuits (ASICs) or Field-Programmable Gate Arrays (FPGAs). Additionally or alternatively, some receiver elements can be implemented using software, or using a combination of hardware and software elements.

In some embodiments, certain functions of receiver 20, e.g., control unit 40, may be implemented using a general-purpose processor, which is programmed in software to carry out the functions described herein. The software may be downloaded to the processor in electronic form, over a network, for example, or it may, alternatively or additionally, be provided and/or stored on non-transitory tangible media, such as magnetic, optical, or electronic memory.

### ECC Decoding Using Cascaded Decoding Stages

As explained above, control unit 40 configures decoding stages 44 to form one or more cascades for iteratively decoding the received input signals. The description that follows shows implementation examples of the decoding stages and the control circuitry. Examples of criteria for allocating decoding stages (and thus cascades of various lengths) to input signals are given further below.

FIG. 2 is a block diagram that schematically illustrates the internal structure of iteration stage 44, in accordance with an embodiment of the present invention. In the present example, the ECC in question comprises a concatenated code—The transmitter produces each input signal by encoding groups of data bits with a Reed-Solomon (RS) code, and then encoding the RS-encoded data with a convolutional code. Each input signal thus comprises a bit stream encoded with the above-described concatenated code.

In some embodiments, each iteration stage 44 receives as input a set of input soft bits computed in modem 32. The input soft bits correspond to the respective bits of a received code word. Each input soft bit comprises an estimated bit value (“0” or “1”) and a soft confidence metric that quantifies the confidence level assigned to the estimated bit value by the modem. Typically, although not necessarily, the input soft bits comprise Log Likelihood Ratios (LLRs).

Iteration stage 44 comprises an ECC decoder 48 followed by an ECC encoder 52. Decoder 48 performs an iteration of the ECC decoding process on the input soft bits. In the present example, decoder 48 decodes the outer RS code and then decodes the inner convolutional code. The decoder may comprise, for example, a block decoder for decoding the RS code and a Viterbi decoder for decoding the convolutional code. Encoder 52 re-encodes the decoded bits produced by decoder 48, so as to produce output soft bits. The encoder may comprise, for example, a convolutional encoder for re-encoding the convolutional code and a block encoder for re-encoding the RS code.

The output soft bits may be used as input soft bits for the next iteration stage 44, if the current iteration stage is not the last stage in its cascade. If the current iteration stage is the last stage in the cascade, encoder 52 may be bypassed, and the decoded bits produced by decoder 48 are used as the decoded output of the cascade.

In some embodiments, encoder 52 sets the confidence metrics of the output soft bits based on the decoding results of decoder 48. In an example embodiment, decoder 48 outputs an indication whether decoding of the RS code was successful or not. Encoder 52 may assign the output soft bits a high confidence level if RS decoding was successful, and a low confidence level if RS decoding has failed.

As another example, in many cases an input signal comprises a known bit pattern at a known location in the data. Such a pattern may comprise, for example, a synchronization pattern used in the applicable communication protocol. A known bit pattern of this sort can be used by encoder 52 to set the confidence metrics of the output soft bits. For example, encoder 52 may check whether the output soft bits produced by decoder 48 at the expected location match the known bit pattern. If a match is found, encoder 52 may assign the output soft bits a high confidence metric. If the output soft bits do not match the known pattern, encoder 52 may assign the output soft bits a low confidence metric. Alternatively, encoder 52 may use any other technique for setting the confidence metrics of the output soft bits.

In some embodiments, iteration stage 44 selects whether to output the output soft bits from encoder 52, or to output the input soft bits without decoding and re-encoding. For example, if RS decoding has failed, it may be advantageous to copy the input soft bits to the output without change. For this purpose, iteration stage 44 further comprises a First-In First-Out (FIFO) buffer 56 and a multiplexer 60 (MUX—denoted MERGE in the figure). FIFO 56 delays the input soft bits by a delay that matches the processing delay of decoder 48 and encoder 52. MUX 60 chooses whether to output the output soft bits or the delayed input soft bits.

In some embodiments, each input signal is interleaved in the transmitter with a long interleaving period that spans multiple RS code words. In these embodiments, each decoding stage 44 comprises a suitable matching de-interleaver (not shown in the figure for the sake of clarity). In these embodiments, bits of two or more code words are interleaved with one another, meaning that a received bit belonging to a given code word may have neighboring bits in the de-interleaver that belong to one or more other code words. Therefore, even if RS decoding has failed in a given iteration stage, it may make sense to transfer the input soft bits to another iteration stage and re-attempt to decode them. The next iteration stage may succeed, for example because the confidence metrics of neighboring bits of other code words (which have been decoded successfully) may be higher in the next iteration, or because neighboring bits from successfully-decoded code words may have been corrected.

FIG. 3 is a block diagram that schematically illustrates an iterative ECC decoder 70, in accordance with an embodiment of the present invention. The configuration of decoder 70 can be used, for example, for implementing decoder 36 of FIG. 1 above.

In the present example, iterative decoder 70 receives input soft bits of N input signals (layers) denoted LAYER 1 . . . LAYER N. Decoder 70 comprises M decoding units 74, each comprising a respective iteration stage 44 (similar to stage 44 of FIG. 2) and respective multiplexers (MUXs) 78 and 82. Decoder 70 further comprises N output MUXs 86 and N respective decoders 90.

In the present example, MUXs 78, 82 and 86 are considered part of the control circuitry that configures iteration stages 44.

MUXs 78, 82 and 86 are controlled by control unit 40 of FIG. 1 (which is also considered part of the control circuitry). By controlling the various MUXs, the control unit is able to allocate cascades of any desired length (i.e., allocate any desired number of decoding iterations) to the N layers.

In each decoding unit 74, MUX 78 is an N-port MUX that receives the N layers as input. By configuring MUX 78, control unit 40 is able to provide any of the N layers as input to the decoding unit.

In a given decoding unit 74, MUX 82 selects whether the decoding unit is the first unit in a cascade (in which case it receives one of the N layers as input from MUX 78) or a middle unit in a cascade (in which case it receives input from a preceding decoding unit).

Each output MUX 86 selects the output of any of the M decoding units 74, and delivers the output soft bits from this decoding unit to the respective decoder 90.

Thus, by controlling MUXs 78, 82 and 86, control unit 40 is able to configure the pool of iteration stages 44 to form any desired number of cascades, each having any desired number of iteration stages, and to allocate each cascade to perform ECC decoding on any desired layer.

The control circuitry configuration shown in FIG. 3 is an example configuration, which is depicted purely for the sake of conceptual clarity. In alternative embodiments, any other suitable control circuitry configuration can be used.

### Adaptive Configuration of Decoding Stages

In various embodiments, control unit 40 may allocate decoding stages to the received input signals (layers) in various ways and based on various parameters or criteria. For example, in some embodiments the received composite signal comprises multiple input signals that possibly differ in modulation, data rate or other transmission parameters. This scenario is common, for example, in a composite DTV channel that carries one or more video signals, one or more audio signals and/or one or more data signals.

In these embodiments, control unit 40 may assign the input signals respective cascades whose lengths (i.e., numbers of iteration stages) depend on the transmission parameters of the input signals. The assignment may also depend on factors such as the Signal-to-Noise Ratio (SNR) with which the composite signal is received. Note that the number of iteration stages assigned to a given input signal may sometimes depend on transmission parameters of other input signals (and not necessarily only on transmission parameters of given input signal).

In an example embodiment, control unit 40 may assign a large number of decoding stages (i.e., a long cascade) to an input signal having a high data rate and/or high-order modulation, and a smaller number of decoding stages (i.e., a shorter cascade) to an input signal having a low data rate and/or low-order modulation. The rationale behind this sort of assignment is that an input signal having a low data rate and/or low-order modulation is typically more resilient to errors than an input signal having a high data rate and/or high-order modulation.

Additionally or alternatively, unit 40 may find that the current SNR is too low for decoding one of the input signals, regardless of the number of iteration stages. In this embodiment, unit 40 may decide not to allocate any decoding stages to this input signal, but rather allocate all the decoding stages to the other input signals.

Another parameter of the input signals that can be considered by unit 40 in allocating decoding stages is the extent of interleaving applied to the various input signals (or simply whether interleaving is used or not). An input signal that has been interleaved is more resilient to errors than a non-interleaved input signal, and the resilience typically increases with interleaving length. Since the extent of interleaving is indicative of error resilience, it can be used as a factor in determining the allocation of decoding stages to input signals.

Additionally or alternatively, control unit 40 may allocate iteration units to input signals depending on factors such as the Bit Error Rate (BER), bit-rate or video quality of the composite signal or individual input signals. As another example, the allocation may depend on the relative importance of each input signal. In a “picture-in-picture” (PIP) application, for example, the smaller inner picture is typically regarded as less important than the larger outer picture, and therefore the former may be assigned fewer iteration units. As yet another example, the allocation may also depend on power consumption considerations.

The above allocation criteria are given purely by way of example. In alternative embodiments, control unit 40 may allocate iteration units to input signals in accordance with any other suitable criterion and/or based on any other suitable factors.

Control unit 40 may set or modify the allocation at various times and in response to various events. For example, unit 40 may initially allocate cascades of iteration stages to input signals when receiver 20 initially tunes to a given channel (i.e., starts to receive a given set of layers). Unit 40 may adapt the allocation, for example, upon detecting a change in SNR, upon detecting a change in the transmission parameters of the layers, or at periodic intervals.

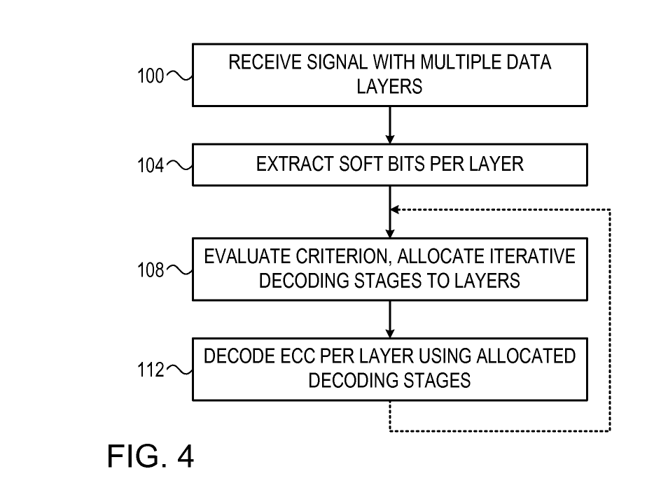

FIG. 4 is a flow chart that schematically illustrates a method for iterative ECC decoding, in accordance with an embodiment of the present invention. The method begins with receiver 20 receiving a composite signal that comprises multiple input signals (layers), at a reception step 100. Modem 32 computes soft bits for the received input signals, at a soft bit extraction step 104. Control unit 40 evaluates the applicable allocation criteria, and allocates cascades of iteration stages to the various input signals, at an allocation step 108. Decoder 36 then decodes the ECC of the various input signals using the respective allocated cascades of iteration stages, at a decoding step 112. Optionally, the method may loop back from step 112 to step 108, for re-evaluation of the allocation criteria and possible re-allocation of iteration stages.

Although the embodiments described herein mainly address video transmission, the methods and systems described herein can also be used in other applications, such as in communication of other types of media or information, broadcast applications, storage applications, among others.

It will thus be appreciated that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. Apparatus, comprising:
a plurality of decoding stages, each configured to perform a decoding iteration of an Error Correction Code (ECC); and
control circuitry, which is configured to receive two or more input signals that carry data encoded with the ECC, to adaptively select an allocation that specifies a respective number of decoding iterations of the ECC to be performed on each of the input signals, to configure the decoding stages in the plurality in one or more cascades in accordance with the allocation, and to decode the input signals using the cascaded decoding stages.

2. The apparatus according to claim 1, wherein the two or more input signals are received over a given communication channel, and wherein the control circuitry is configured to adaptively select the allocation based on a condition of the communication channel.

3. The apparatus according to claim 1, wherein the control circuitry is configured to adaptively select the allocation based on one or more parameters of the input signals.

4. The apparatus according to claim 3, wherein the parameters comprise respective data rates of the input signals.

5. The apparatus according to claim 3, wherein the parameters comprise respective modulation schemes of the input signals.

6. The apparatus according to claim 3, wherein the parameters comprise respective extents of interleaving applied to the input signals.

7. The apparatus according to claim 1, wherein a given decoding stage is configured to receive input soft bits, to perform the decoding iteration on the input soft bits, and to re-encode the decoded input soft bits so as to produce output soft bits.

8. The apparatus according to claim 7, wherein the given decoding stage is configured to select whether to provide as output the output soft bits or the received input soft bits.

9. The apparatus according to claim 8, wherein the given decoding stage is configured to set respective confidence metrics of the output soft bits depending on a success indication of decoding the input soft bits.

10. The apparatus according to claim 8, wherein a predefined location in the data contains a predefined bit pattern, and wherein the given decoding stage is configured to set respective confidence metrics of the output soft bits depending on whether the decoded input soft bits at the predefined location match the predefined bit pattern.

11. A method, comprising:
receiving two or more input signals that carry data encoded with an Error Correction Code (ECC), for decoding by a plurality of decoding stages that are each configured to perform a decoding iteration of the ECC;
adaptively selecting an allocation that specifies a respective number of decoding iterations of the ECC to be performed on each of the input signals;
configuring the decoding stages in the plurality in one or more cascades in accordance with the allocation; and
decoding the input signals using the cascaded decoding stages.

12. The method according to claim 11, wherein adaptively selecting the allocation comprises choosing the allocation based on a condition of a communication channel over which the input signals are received.

13. The method according to claim 11, wherein adaptively selecting the allocation comprises choosing the allocation based on one or more parameters of the input signals.

14. The method according to claim 13, wherein the parameters comprise respective data rates of the input signals.

15. The method according to claim 13, wherein the parameters comprise respective modulation schemes of the input signals.

16. The method according to claim 13, wherein the parameters comprise respective extents of interleaving applied to the input signals.

17. The method according to claim 11, wherein decoding the input signals comprises, in a given decoding stage, receiving input soft bits, performing the decoding iteration on the input soft bits, and re-encoding the decoded input soft bits so as to produce output soft bits.

18. The method according to claim 17, wherein performing the decoding iteration comprises selecting in the given decoding stage whether to provide as output the output soft bits or the received input soft bits.

19. The method according to claim 17, wherein performing the decoding iteration comprises setting respective confidence metrics of the output soft bits depending on a success indication of decoding the input soft bits.

20. The method according to claim 17, wherein a predefined location in the data contains a predefined bit pattern, and wherein performing the decoding iteration comprises setting respective confidence metrics of the output soft bits depending on whether the decoded input soft bits at the predefined location match the predefined bit pattern.

21. Apparatus, comprising:
a receiver front-end; and
a modem, which comprises a plurality of decoding stages, each configured to perform a decoding iteration of an Error Correction Code (ECC), wherein the modem is configured to receive two or more input signals that carry data encoded with the ECC, to adaptively select an allocation that specifies a respective number of decoding iterations of the ECC to be performed on each of the input signals, to configure the decoding stages in the plurality in one or more cascades in accordance with the allocation, and to decode the input signals using the cascaded decoding stages.
